(19) United States
(12) Patent Application Publication
(10) Pub. No.: US 2002/0140321 A1
(43) Pub. Date: Oct. 3, 2002

(54) Coated electroactive bender actuator

(76) Inventor: Larry G. Waterfield, Peoria, IL (US)

Correspondence Address: CATERPILLAR INC., 100 N.E. ADAMS STREET, PATENT DEPT., PEORIA, IL, 616296490

(21) Appl. No.: 09/818,308

(22) Filed: Mar. 27, 2001

(51) Int. Cl. H01L 41/04

(52) U.S. Cl. 310/330; 310/363; 310/364

(57) ABSTRACT

An electroactive bender actuator includes one or more electroactive layers disposed at least in part between pairs of spaced electrode layers. At least a portion of the outer surface of the actuator is coated with a coating material in order to enhance the performance of the actuator, reduce the likelihood of electrical shorting between the electrode layers and improve wear resistance. The coating may be applied to the actuator by a vapor deposition, spraying or dipping process. Masking may be used to leave a selected area of the actuator outer surface uncoated.

### TECHNICAL FIELD

The present invention relates generally to actuator devices and, more particularly, to an actuator device comprising at least one active layer and at least a pair of parallel spaced electrodes.

### BACKGROUND

Electroactive bender actuators have long been used in a wide range of applications, including switches, pumps, valves and other devices. Such electroactive bender actuators typically comprise at least one electroactive layer located between a pair of electrodes. When the electrodes are energized, they cause the electroactive layer to bend in order to move a device situated against or secured to the actuator in order to do some function, such as open or close a valve. Several different high performance actuators have been developed, such as those disclosed in U.S. Pat. Nos. 5,471,721 and 5,632,841, which are able to improve the output of such actuators.

One difficulty with using a conventional actuator in a pump or valve is that pumps and valves are commonly made of metal. In a bare electroactive bender actuator, one or more parts of the actuator may accidentally come into electrical contact with the pump or valve causing the actuator to short and malfunction. In order to prevent such shorting, an actuator must be electrically insulated from the structure in which it is located, including the actuator=s clamping apparatus and the load or orifice that the bender pushes against or contacts. For example, when a bender actuates directly against an orifice in order to control a fluid flow, either the actuator or the orifice surface is made non-conducting. For example, U.S. Pat. No. 5,079,479 is directed to an actuator having a void on the bender or actuator=s outer electrode. Although this void does insulate the actuator from the orifice seat, it creates an undesirable non-uniform excitation of the electroactive material which can lead to stress concentrators and possible failure. In another example, U.S. Pat. No. 4,492,360, the orifice seat is made of insulating plastic. Plastics, however, have undesirable sealing properties such as a low modulus of elasticity and are subject to deformation after many cycles or repetitions. Such deformation is even more apparent when the ultra high performance actuators such as those disclosed in U.S. Pat. Nos. 5,471,721 and 5,632,841 are used.

Often, the electroactive bender actuators are immersed in fluid during use. As a result, the chemical or dielectric properties of the fluid are of concern. If the fluid is strongly basic or alkaline, or is a strong oxidizer, the fluid may degrade the layers of the actuator.

In addition, electroactive bender actuators are frequently operated at high voltages (such as 20 kV/cm). Therefore, when such actuators are immersed in a fluid, electrical shorting can occur between the electrode layers. Additionally, contaminants such as ions or metal flakes may enter the fluid, thus increasing the chances of electrical shorting between the electrode layers.

Because the dielectric strength of air is on the same order of magnitude of the required E field needed to get maximum performance from many electroactive materials, the electrode layers are offset so that their outer edges are not generally aligned or in registry to lie in common planes but rather are staggered so that outer edges of one electrode layer extend beyond outer edges of the other electrode layer to prevent shorting.

Thus, there is a need for an electroactive bending actuator that is easier to design and manufacture than heretofore known actuators. There is also a need for an electroactive bending actuator that is more readily adaptable for use in environments that may otherwise cause chemical degradation of the actuator or electrical shorting of the actuator.

### SUMMARY OF THE INVENTION

While the invention will be described in connection with certain embodiments, it will be understood that the invention is not limited to these embodiments. On the contrary, the invention includes all alternatives, modifications and equivalents as may be included within the spirit and scope of the present invention.

An electroactive bender actuator is provided having a coating covering at least a portion of the outer surface of the actuator. The electroactive bender actuator comprises a pair of parallel spaced electrode layers and an electroactive layer disposed at least in part between the electrode layers. The electroactive layer may be a ceramic material, a piezoelectric layer, an electrostrictive layer or any other equivalent material. The coating may cover the entire outer surface of the actuator or only cover the outer edges of the different layers of the actuator.

The coating may be applied by dipping the actuator in the coating material and allowing the coating material to dry on the outer surface of the actuator. Alternatively, the coating may be applied to the actuator through a spraying or vapor deposition process. A portion of the outer surface of the actuator may be masked in order to cover a pre-selected area of the actuator during the coating process. After the coating step has been completed, the mask may be removed in order to expose the uncoated area of the actuator.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a diagrammatic side elevational view showing an illustrative operating environment for an electroactive bender actuator according to one embodiment of the invention;

FIG. 2 is an enlarged view of the circled area 2 of FIG. 1, showing modification of the electroactive bending actuator of FIG. 1 in accordance with the principles of one embodiment of the present invention;

FIG. 2A is a view similar to FIG. 2, illustrating an electroactive bending actuator according to one aspect of one embodiment of the present invention;

FIG. 2B is a view similar to FIG. 2, illustrating an electroactive bending actuator according to another aspect of one embodiment of the present invention;

FIG. 3 is a perspective view of a spraying process in accordance with the principles of one embodiment of the present invention for applying a coating over a masked area on an electroactive bender actuator;

FIG. 3A is a perspective view of the actuator of FIG. 3 with the mask being removed; and

FIG. 4 is a diagrammatic side elevational view illustrating a representative vapor deposition process used to coat the actuator of one embodiment of the present invention.

### DETAILED DESCRIPTION

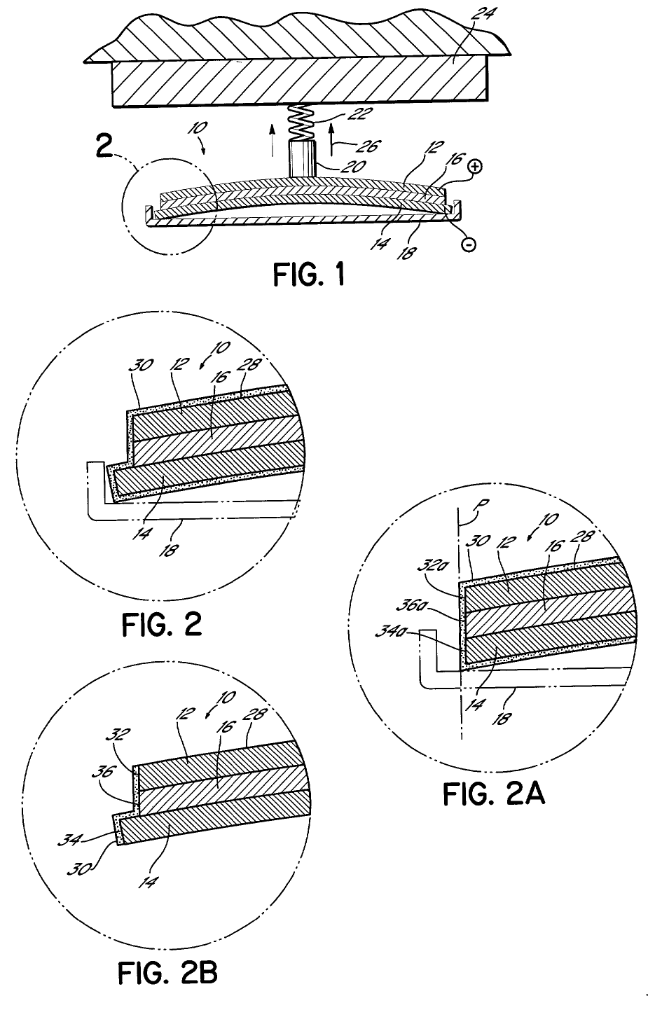

With reference to the figures, and to FIG. 1 in particular, an illustrative operating environment for an electroactive bender actuator 10 is shown. Although one operating environment for the actuator is illustrated by way of example, those skilled in the art will appreciate that the electroactive bender actuator 10 of the present invention may be used in many different operating environments without departing from the spirit and scope of the present invention.

The electroactive bender actuator 10 illustrated in FIG. 1 comprises a pair of spaced parallel electrodes, including an upper electrode 12 and a lower electrode 14. Disposed at least in part between the electrode layers 12,14 is an electroactive layer 16. The electrodes 12,14 are connected to positive and negative terminals of a power source (not shown) that is operable to energize and cause bending movement of the actuator 10 as is known in the art. Although one configuration of actuator is illustrated having three layers, the actuator of the present invention may comprise any number of layers and of any ratio of thickness.

In the environment illustrated in FIG. 1, the actuator 10 rests in a support structure 18. Support structure 18 is designed to permit bending movement of the actuator 10 when it is energized while maintaining registry of the actuator 10 with other components that operate in association with the actuator. Although one configuration of support structure 18 is illustrated, this application is not intended to limit the support structure, which may assume any of numerous configurations.

In the illustrative operating environment of FIG. 1, a mass 20 and spring 22, representative of a valve, are positioned between the actuator 10 and a mechanical ground 24. Upon activation of the actuator 10, the mass 20 is moved upwardly in the direction of arrows 26 and against the force exerted by spring 22. The movement of the actuator 10 may close a valve, open a valve or do any of numerous functions. This application is not intended to limit in any way the applicability of the actuator 10.

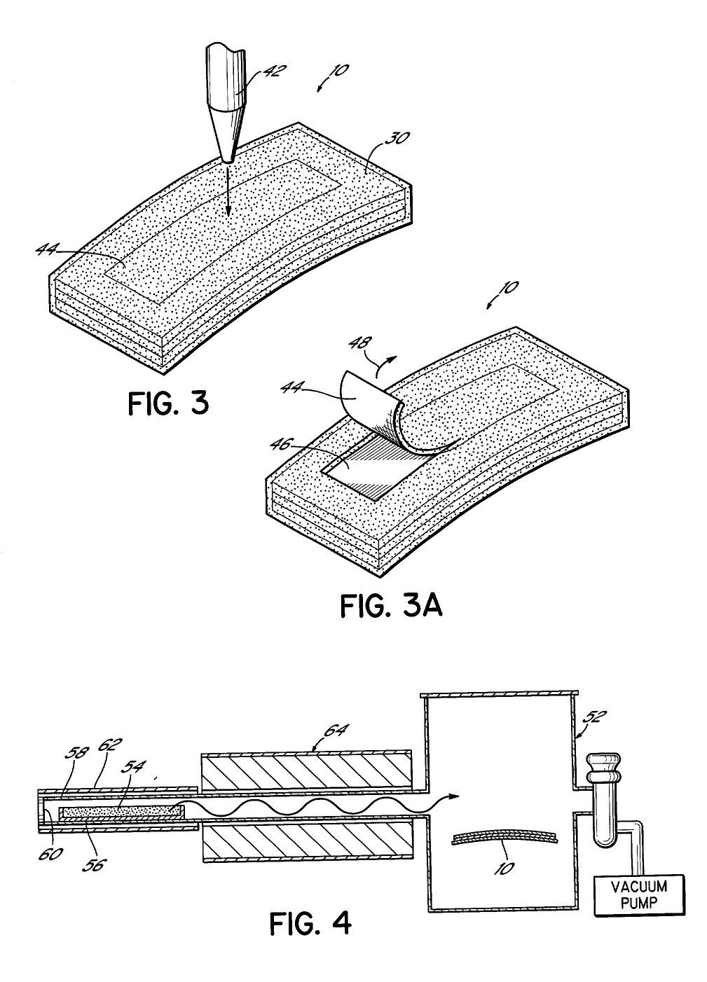

Because the support 18 and mass 20 may be made of metal, it is desirable to electrically insulate the outer surface 28 of the actuator 10 from the support 18 and mass 20. Consequently, and in accordance with the principles of one embodiment of the present invention, the actuator may be coated, as illustrated in FIGS. 2, 2A and 3, with an insulating coating 30. The coating 30 may cover the entire outer surface 28 of the actuator 10, as illustrated in FIGS. 2, 2A and 3 so that the actuator 10 is electrically insulated from the support 18 and the mass 20. Alternatively, the coating 30 may only cover the outer edge surfaces 32, 34 of the electrodes 12, 14, respectively, and the outer edge surface 36 of the electroactive layer 16, as illustrated in FIG. 2B or other portions of the actuator 10, as appropriate. The extent of the coating 30 on actuator 10 will be application specific.

As illustrated in FIGS. 2 and 2B, the outer edges 32 of the upper electrode 12 may be offset from the outer edges 34 of the lower electrode 14 so that the outer edges 34 of the lower electrode 14 extend beyond the outer edges 32 of the upper electrode 12. Such an offset has typically been required in known uncoated actuators in order to prevent electrical shorting when high voltages are used to activate the actuator 10 by increasing the distance between the edges 32, 34 of the electrodes 12, 14.

As illustrated in FIG. 2A, by coating the entire edge of the actuator 10, the outer edge surfaces 32a and 34a of the upper and lower electrodes 12, 14, respectively, may be generally aligned to be in registry with each other, i.e., the outer edge surfaces 32a and 34a lie in generally common planes (one plane “P” shown in FIG. 2A) about the sides of the actuator 10. Further, the outer edge surface 36a of the middle electroactive layer 16 may be generally aligned to be in registry with the outer edges 32a, 34a of the upper and lower electrodes 12, 14, respectively, to lie in the generally common planes P. Regardless of whether the outer edge surfaces of the layers are offset from one another or are generally aligned in registry to lie in common planes, the coating 30 typically covers the entire outer edge surfaces of the actuator 10 in order to prevent shorting. Such coating 30 enables the actuator 10 to be used in environments not heretofore possible such as in flow paths of fluids which are strongly basic or alkaline. The coating 30 helps prevent degradation of the layers of the actuator due to the nature of the fluid. Moreover, the coating 30 provides greater freedom in the design and manufacturing of the actuator 10 by significantly reducing occurrences of electrical shorting between the upper and lower electrodes 12, 14.

The coating material is preferably a material which is capable of electrically insulating the actuator 10, and preferably has good dielectric properties. Preferable coatings which have good dielectric properties are polytetrafluoroethylene (TEFLONJ) and parylene. Other coating materials having good wear resistant properties are silicone impregnated with aluminum oxide and phosphate glass filled with chromium carbide. Other appropriate coatings known to those skilled in the art may also be used.

The coating may be applied using numerous methods known to those skilled in the art. One method of coating the actuator with parylene is a vapor deposition process. By way of example, an illustrative vapor deposition process employed by Paratronix, Inc. of Attleboro, Mass. is shown in FIG. 4, although it is contemplated that other parylene vapor deposition processes are possible as well. Further, coating materials other than parylene may be used as well in a vapor deposition process to coat the outer surface of the actuator 10. Using a vapor deposition process such as the one illustrated in FIG. 4 enables one to accurately control the thickness of the coating in order to achieve a uniform coating over the outer surface of the actuator.

Referring to FIG. 4 there is illustrated an actuator 10 residing in a vapor deposition chamber 52 that is heated to about 250° C. Dimer 54 is placed in an aluminum foil cup or “boat” 56 that is located in a glass tube 58. The coating thickness deposited on the actuator 10 is determined by the volume of dimer 54 placed in the boat 56. The glass tube 58 is covered with an end cap 60. A radiant heater 62 operating at about 175° C. is cycled “on” and “off” to heat the dimer which changes from a solid to a vapor. The dimer molecules move from left to right in FIG. 4 toward the open end of the glass tube 58 due to a reduced pressure at the open end of the tube 58 near the deposition chamber 52. The dimer molecules move into a pyrolysis zone 64 which is heated at about 680° C. to cleave the dimer into two divalent radical monomers. The monomer molecules enter into the deposition chamber 52 and re-form as a long chain polymer on all surfaces of the actuator 10. Although one specific vapor deposition process is illustrated in FIG. 4 and described above, other apparatus and processes known in the art may be used to coat actuators using a vapor deposition process without departing from the spirit and scope of the present invention.

FIG. 3 illustrates one configuration of actuator 10 coated with coating layer 30. In this embodiment, the coating material is sprayed onto outer surfaces of the actuator 10 via a liquid dispensing nozzle 42. Although only one nozzle 42 is illustrated, any number of nozzles or similar devices may be used to coat the actuator 10 with a coating 30, such as polytetrafluoroethylene (TEFLON™) or other sprayable liquid material. The actuator 10 may include a mask 44 covering an area 46 of the actuator. Once the entire surfaces of the actuator 10 is coated, as illustrated in FIG. 3, the mask 44 is removed by pulling the mask 44 in the direction of arrow 48, thus exposing the uncovered area 46. Such masking may be used to coat only a selected portion of the outer surface of the actuator 10. For example, the upper or lower outer surfaces of the actuator 10 may be left uncoated using such a masking process or, as shown in FIG. 3A, only a selected area 46 may be left uncoated to expose a portion of the outer surface 28. It is contemplated that the coating material can be removed to expose one or more uncovered areas of the actuator 10 in other ways as well. This application is not intended to limit the areas which may be coated and the areas which may be left uncoated.

An alternative process for coating actuator 10 may include dipping the actuator 10 into a liquid coating material, such as epoxy, and then allowing the coating material to dry on the outer surfaces of the actuator 10. Those skilled in the art will appreciate the many different processes available for applying a coating to actuator 10 without departing from the spirit and scope of the present invention.

### INDUSTRIAL APPLICABILITY

With reference to the drawings and in operation, an electroactive bender actuator 10 is at least partially coated with a coating material. The electroactive bender actuator 10 includes an upper electrode 12, a lower electrode 14 and an electroactive layer 16 disposed at least in part between the electrode layers 12,14.

The coating 30 may cover the entire outer surface of the electroactive bender actuator 10 or, in the alternative, only a portion thereof. For example, the coating may cover only the outer edge surfaces of the electroactive bender actuator 10 to prevent shorting between the electrode layers of the actuator 10.

With such a protective and insulating coating, the actuator may be used in a variety of fluids and in a variety of operating environments. A coated actuator may be used in pumps, valves, or other devices having metal components in contact with the actuator 10 with a reduced likelihood of shorting when a voltage is applied to the electrodes of the actuator 10. Therefore, the actuator 10 is more readily adaptable for use in environments that may otherwise cause chemical degradation or wear of the actuator. By selectively coating the outer edges of the actuator 10, the edges of the electrodes 12, 14 may be made generally aligned or in registry to lie in common planes about the sides of the actuator 10, as well as the outer edges of the electroactive layer 16. This simplifies design and manufacture of the actuator 10.

The coating should be thick enough to electrically insulate the outer surface of the actuator but yet not so thick as to inhibit the performance of the actuator. The appropriate thickness may be determined by ways known to those skilled in the art. Different methods, such as dipping, spraying, and vapor deposition, may be used to ensure a uniform thickness of coating over the desired surfaces of the actuator.

Other aspects and features of the present invention can be obtained from a study of the drawings, the disclosure and the appended claims.

What is claimed is:

1. An electroactive bender actuator, comprising:
a pair of spaced electrodes;
an electroactive layer disposed at least in part between and coupled with said electrodes; and
an insulating coating operable to be applied by vapor deposition covering at least a portion of an outer surface of said actuator.

2. The electroactive bender actuator of claim 1 wherein said coating covers the entire outer surface of said actuator.

3. The electroactive bender actuator of claim 1 wherein said coating is silicon impregnated with aluminum oxide.

4. The electroactive bender actuator of claim 1 wherein said coating is phosphate glass filled with chromium carbide.

5. The electroactive bender actuator of claim 1 wherein said coating is polytetrafluoroethylene.

6. The electroactive bender actuator of claim 1 wherein said coating is parylene.

7. The electroactive bender actuator of claim 1 wherein said electrode layers have outer edges that are offset from one another.

8. The electroactive bender actuator of claim 1 wherein said electrode layers have outer edges that are generally aligned to lie in common planes.

9. The electroactive bender actuator of claim 1 wherein only the outer edges of said electrode layers and said electroactive layer are coated.

10. An electroactive bender actuator, comprising:
a pair of spaced electrode layers having a plurality of outer edge surfaces that are generally aligned to lie in common planes; and
an electroactive layer disposed at least in part between and coupled with said electrode layers and having a plurality of outer edge surfaces.

11. The electroactive bender actuator of claim 10 further comprising an insulating coating covering said outer edge surfaces of said electroactive and electrode layers.

12. The electroactive bender actuator of claim 11 wherein said coating covers the entire outer surface of said actuator.

13. The electroactive bender actuator of claim 11 wherein said coating is silicon impregnated with aluminum oxide.

14. The electroactive bender actuator of claim 11 wherein said coating is phosphate glass filled with chromium carbide.

15. The electroactive bender actuator of claim 11 wherein said coating is applied using a vapor deposition process.

16. The electroactive bender actuator of claim 11 wherein said coating is polytetrafluoroethylene.

17. The electroactive bender actuator of claim 11 wherein said coating is parylene.

18. The electroactive bender actuator of claim 11 wherein said outer edge surfaces of said electroactive layer are generally aligned to lie in common planes with said outer edge surfaces of said electrode layers.

19. A method of manufacturing an electroactive bender actuator having a pair of spaced electrode layers and an electroactive layer disposed at least in part between said electrode layers, said electrode layers and said electroactive layer having respective outer edges, said method comprising:
aligning said outer edges generally in a common plane; and
coating said outer edges of said electrode layers and said electroactive layer with an insulating material.

20. The method of claim 19 wherein said coating comprises dipping said electroactive bender actuator in said insulating material and allowing said insulating material to dry on said outer edges of said electrode layers and said electroactive layer.

21. The method of claim 19 wherein said coating comprises coating said outer edges of said electrode layers and said electroactive layer with said insulating material using a vapor deposition process.

22. The method of claim 19 wherein said coating comprises spraying said insulating material onto at least said outer edges of said electrode layers and said electroactive layer.

23. The method of claim 19, further comprising coating at least a portion of an outer surface of said electroactive bender actuator with said insulating material.

24. The method of claim 19 further comprising masking a portion of said electroactive bender actuator with a mask prior to said coating.

25. The method of claim 24 further comprising removing said mask to expose an uncoated surface of said electroactive bender actuator.
